(19) United States
(12) Patent Application Publication
(10) Pub. No.: US 2015/0123697 A1
(43) Pub. Date: May 7, 2015

(54) METHODS AND APPARATUSES FOR AC/DC CHARACTERIZATION

(71) Applicant: QUALCOMM Incorporated, San Diego, CA (US)

(72) Inventors: James LeRoy BLAIR, Ramona, CA (US); Hongjun Menzo YAO, San Diego, CA (US)

(21) Appl. No.: 14/466,792

(22) Filed: Aug. 22, 2014

Related U.S. Application Data
(60) Provisional application No. 61/901,335, filed on Nov. 7, 2013.

(51) Int. Cl. G01R 31/26; G01R 1/073

(52) U.S. Cl. CPC G01R 31/2637; G01R 31/2601; G01R 1/07342
USPC 324/762.02

(57) ABSTRACT

Aspects of an apparatus for characterizing an integrated circuit device are provided. The apparatus includes a first connection circuit configured to selectively couple at least one terminal of the integrated circuit device to a termination circuit for AC loopback and a second connection circuit configured to selectively couple the at least one terminal of the integrated circuit device to a test resource for DC characterization. In another aspect, an apparatus for characterizing an integrated circuit is provided. The apparatus includes a board configured to couple to the integrated circuit and a resource to characterize the integrated circuit. The board includes means for detecting physical misalignment of the board and the resource to characterize the integrated circuit.

### CLAIM OF PRIORITY UNDER 35 U.S.C. §119

The present application for patent claims priority to Provisional Application No. 61/901,335, filed Nov. 7, 2013, and assigned to the assignee hereof and hereby expressly incorporated by reference herein.

### FIELD

The present disclosure relates generally to methods and apparatuses for integrated circuit (IC) characterization. More particularly, the present disclosure relates to methods, apparatuses, and electronic circuits for alternating current (AC) and/or direct current (DC) performance characterization.

### BACKGROUND

As uses of wireless devices grow, so does the need to manufacture and to characterize semiconductor devices in an efficient manner. Characterization of the semiconductor devices, such as the logic IC chips and the memory IC chips incorporated into a wireless device, may be time consuming and therefore, costly. As the logic devices and the memory devices have become smaller and at the same time more powerful and capable, the ICs used in the devices have also become more complex. One design challenge is to simplify the process for characterizing the semiconductor devices.

### SUMMARY

Aspects of an apparatus for characterizing (evaluating) an integrated circuit device are provided. The apparatus includes a first connection circuit configured to selectively couple at least one terminal of the integrated circuit device to a termination circuit for alternate current (AC) loopback and a second connection circuit configured to selectively couple the at least one terminal of the integrated circuit device to a test resource for direct current (DC) characterization.

Aspects of an apparatus for characterizing an integrated circuit are provided. The apparatus includes a board configured to couple to the integrated circuit and a resource to characterize the integrated circuit. The board includes means for detecting physical misalignment of the board and the resource to characterize the integrated circuit.

It is understood that other aspects of apparatus and methods will become readily apparent to those skilled in the art from the following detailed description, wherein various aspects of apparatus and methods are shown and described by way of illustration. As will be realized, these aspects may be implemented in other and different forms and its several details are capable of modification in various other respects. Accordingly, the drawings and detailed description are to be regarded as illustrative in nature and not as restrictive.

### BRIEF DESCRIPTION OF THE DRAWINGS

Various aspects of apparatus and methods will now be presented in the detailed description by way of example, and not by way of limitation, with reference to the accompanying drawings, wherein:

FIG. 1 is a block diagram of an exemplary PoP-HAT embodiment.

FIG. 2 is a diagram of a top view of an exemplary PoP-HAT apparatus.

FIG. 3 is a block diagram of a side view of an exemplary PoP-HAT apparatus engaged with a test board.

FIG. 4 is a block diagram illustrating a connection for a request pin of an exemplary misalignment detection configuration.

FIG. 5 is a block diagram illustrating a PoP-HAT board misalignment.

FIG. 6 is a block diagram of an exemplary PoP-HAT configuration with multiple PoP-HAT boards.

FIG. 7 is a block diagram of an exemplary PoP-HAT configuration for pin-to-pin and pin-to-package leakage current characterization.

FIG. 8 is a flowchart of operations of an exemplary PoP-HAT apparatus.

### DETAILED DESCRIPTION

The detailed description set forth below in connection with the appended drawings is intended as a description of various exemplary embodiments of the present invention and is not intended to represent the only embodiments in which the present invention may be practiced. The detailed description includes specific information for the purpose of providing a thorough understanding of the present invention. However, it will be apparent to those skilled in the art that the present invention may be practiced without these specific details. In some instances, well-known structures and components are shown in block diagram form in order to avoid obscuring the concepts of the present invention. Acronyms and other descriptive terminology may be used merely for convenience and clarity and are not intended to limit the scope of the invention.

Various apparatus and methods presented throughout this disclosure may be implemented in various forms of hardware. By way of example, any of these apparatus or methods, either alone or in combination, may be implemented as an integrated circuit, or as part of an integrated circuit. The integrated circuit may be an end product, such as a microprocessor, a digital signal processor (DSP), an application specific integrated circuit (ASIC), programmable logic, or any other suitable integrated circuit. Alternatively, the integrated circuit may be integrated with other chips, discrete circuit elements, and/or other components as part of either an intermediate product, such as a motherboard, or an end product. The end product can be any suitable product that includes integrated circuits, including by way of example, a cellular phone, personal digital assistant (PDA), laptop computer, a desktop computer (PC), a computer peripheral device, a multimedia device, a video device, an audio device, a global positioning system (GPS), a wireless sensor, or any other suitable device.

The word “exemplary” is used herein to mean serving as an example, instance, or illustration. Any embodiment described herein as “exemplary” is not necessarily to be construed as preferred or advantageous over other embodiments. Likewise, the term “embodiment” of an apparatus or method does not require that all embodiments of the invention include the described components, structure, features, functionality, processes, advantages, benefits, or modes of operation.

When a “signal” is reference, the term may include the conductor carrying the described signal. The term “connection” may include a signal line. The terms “connected,” “coupled,” or any variant thereof, mean any connection or coupling, either direct or indirect, between two or more elements, and can encompass the presence of one or more intermediate elements between two elements that are “connected” or “coupled” together. The coupling or connection between the elements can be physical, logical, or a combination thereof. As used herein, two elements can be considered to be “connected” or “coupled” together by the use of one or more wires, cables and/or printed electrical connections, as well as by the use of electromagnetic energy, such as electromagnetic energy having wavelengths in the radio frequency region, the microwave region and the optical (both visible and invisible) region, as several non-limiting and non-exhaustive examples. References to the term input/output or I/O may refer to the I/O terminal or the I/O pin of a semiconductor device.

Any reference to an element herein using a designation such as “first,” “second,” and so forth does not generally limit the quantity or order of those elements. Rather, these designations are used herein as a convenient method of distinguishing between two or more elements or instances of an element. Thus, a reference to first and second elements does not mean that only two elements can be employed, or that the first element must precede the second element.

As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of the stated features, integers, steps, operations, elements, and/or components, but do not preclude the presence or addition of one or more other features, integers, steps, operations, elements, components, and/or groups thereof.

Various apparatus and methods presented throughout this disclosure may be implemented in various forms of hardware. By way of example, any of these apparatus or methods, either alone or in combination, may be implemented as an integrated circuit, or as part of an integrated circuit. The integrated circuit may be an end product, such as a microprocessor, a digital signal processor (DSP), an application specific integrated circuit (ASIC), programmable logic, or any other suitable integrated circuit. Alternatively, the integrated circuit may be integrated with other chips, discrete circuit elements, and/or other components as part of either an intermediate product, such as a motherboard, or an end product. The end product can be any suitable product that includes integrated circuits, including by way of example, a cellular phone, personal digital assistant (PDA), laptop computer, a desktop computer (PC), a computer peripheral device, a multimedia device, a video device, an audio device, a global positioning system (GPS), a wireless sensor, or any other suitable device.

Various aspects of apparatuses and electronic circuits for AC/DC performance characterization are provided. The exemplary embodiments, e.g., the PoP High-Fidelity Aggregator/Terminator or PoP-HAT, are provided with respect to the package-on-package or PoP IC assembly technology. The exemplary embodiments may further be described with respect to the testing of an integrated circuit or IC attached or coupled to the PoP-HAT apparatus or board. However, as those skilled in the art will readily appreciate, aspects and applications of the disclosure may not be limited to the described exemplary embodiments. Accordingly, all references to a specific application are intended only to illustrate exemplary aspects of the apparatuses and electronic circuits with the understanding that such aspects may have a wide differential of applications. For example, the apparatuses and electronic circuits for AC/DC performance characterization described herein are not limited to device testing. Moreover, while the POP-HAT configuration and apparatus are described as examples, the scope of the disclosure is not limited thereto.

The PoP configuration may include a “stacked” memory interface. For example, the PoP chip may include a double data rate (DDR) memory stacked on a logic device, such as a processor for a wireless application. The multiple pins on the multiple surfaces may be tested and characterized before the PoP chip is integrated with a DDR memory and into a consumer product (e.g., a wireless device). Such testing and characterization may typically require multiple testing passes in order to ensure complete testing and characterization of a device. For example, each PoP device may undergo a two-pass (FT1 and FT2) testing process in order to fully evaluate chip functionality. During the FT1 testing, the testing evaluates the AC full-speed (a.k.a. at-speed) loopback characteristics of the DDR I/Os under no-load conditions concurrently with the testing of the underside ball grid array (BGA) contacts. AC loopback is typically applied to an I/O or transceiver terminal for AC performance characterization. In one implementation, the I/O terminal outputs an AC signal, which is returned or loop-backed and received by the same terminal.

The second pass testing FT2 establishes I/O continuity and then evaluates the DDR I/O DC characteristics. In one example, the FT2 testing characterizes the DDR I/O for continuity (e.g., device pin/tester connection and electro-static discharge diode verification), I/O leakage current (e.g., pin/pin and pin/package), and output load current withstanding (e.g., V_{OH}MIN/V_{OL}MAX at rated load current). The FT2 testing may consume considerable testing resources and time and generally results in significant additional production costs. In another aspect, it is usual and customary for FT1 and FT2 testing to be conducted over a temperature range of −40° C. to +110° C.

When a test resource, such as the tester digital channels or DIGCHs, are plentiful and/or the device test platform (e.g., load board) has a limited number of IC devices under test (DUT) spots, the FT1 and FT2 may be combined using memory direct connection (e.g., high signal integrity or “DC to daylight” interface). However, the combined testing requires that each AC active memory pin (which may be 120 or higher for some memories) is served by a DIGCH tester resource to afford the requisite 50Ω transmission line termination for each active I/O.

The first pass testing FT1 provides for testing of the DUT bottom BGA pins/contacts, which may have a count of 990 pins or more. In addition, testing data patterns for the PoP DDR AC loopback testing are evaluated at-speed in open pin (e.g., no load) conditions. Passing devices are then subjected to the FT2 test environment. In the FT2 test environment, only the DC characteristics of the PoP DDR I/Os are measured and verified. This test regimen may result in significant expense for both non-recurring and recurring aspects for FT2 testing. Moreover, the test scenario creates a potential DUT test escape (e.g., erroneously passing a device) in that a memory I/O passes the loopback test with no loads may not consistently pass an operational scenario under actual operations with loads.

In one aspect, the apparatuses and electronic circuits described infra allow for both the DC and loaded AC testing of the I/Os in a single pass. The issues associated with FT2 (such as part handling and testing, FT2 continuity failure associated re-testing, and PoP device BGA ball damage) are reduced or eliminated, while mitigating ESD exposure. Under an ideal FT1 test scenario, the challenge is to meet these DC and loaded AC test requirements while using a minimum amount of tester resources to facilitate multi DUT, high DUT pin count AC/DC testing in a single pass. The PoP-HAT described infra provides the full-load testing at rated AC and DC load limits in a single testing pass of multiple DUTs. As a result, the test strategy is cost effect and affords PoP-HAT electrical current-resistance (I-R) loss calibration as well. One embodiment provides pin-specific, high-signal integrity 50Ω load application for the AC loopback test as well as aggregated DC measurements. The PoP-HAT requires fewer tester resources than prior testing configurations and also enables testing load boards with greater numbers of DUTs. As one example, an eight DUT top/bottom PoP-HAT load board would afford a single pass test platform.

Aspects of the present disclosure provide methods and apparatus to combine the FT1 and FT2 testing to reduce production costs, to maximize test platform DUT count while utilizing a minimum of tester resources, and to evaluate the I/O AC characteristics under high-fidelity, full-load conditions. The combined FT1/FT2 tests may be run over a temperature range. In addition, the testing solution may support both hand test with +110° C. Thermal Forcing Unit (TFU) and chambered/heated chuck handler production test environments. The testing configuration may use a number of digital channels to support testing as described. For load boards of two DUTs, standard tester configuration may provide sufficient digital channels to complete single pass PoP top and bottom testing.

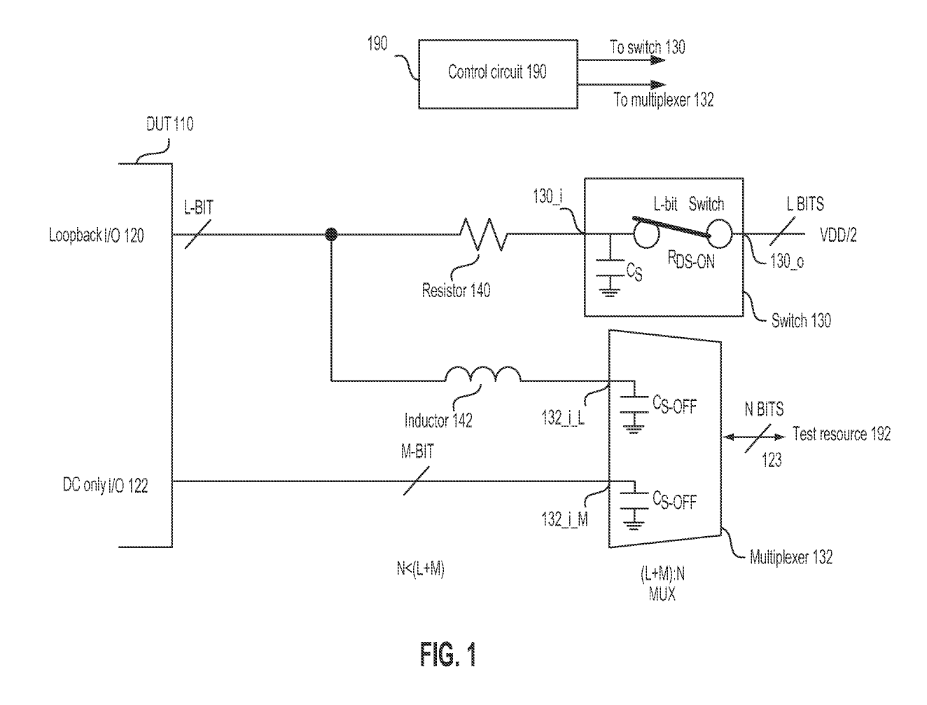

FIG. 1 is a block diagram of an exemplary PoP-HAT embodiment. The PoP-HAT apparatus (e.g., a circuit card assembly or CCA; or PoP-HAT board) is populated with an L-bit wide switch 130 (e.g., an L-bit wide, single-pole-single-throw or SPST solid state switch) and an L-plus-M-bit multiplexer 132 (e.g., signal aggregation multiplexer). The switch 130 selectively connects the L-bit input terminals 130_{—}i to the L-bit output terminals 130_{—}o. Each of the input terminals 130_{—}i is coupled to an equivalent capacitor C_{S} (e.g., the inherent or parasitic capacitance associated with the input terminal within the switch 130). In a CLOSED position (e.g., the loopback I/O 120 is connected to the reference voltage supply VDD/2), the input terminal 130_{—}i may be connected to the output terminal 130_{—}o via an equivalent resistor R_{DS}-ON. The output terminals 130_{—}o may be provided to a reference voltage supply VDD/2. The multiplexer 132 selects from among the L+M input terminals (132_{—}i_L and 132_{—}i_M) for the N-bit outputs 123. The N-bit outputs 123 are provided to the test resource 192 (e.g., DIGCH) for DC testing and characterization. In one implementation, the number of L+M bits is substantially greater than the number of bits in N. In the case an input terminal (e.g., 132_{—}i_L) is not selected for the outputs 123, the capacitance on the input terminal is equivalent to the capacitor CS-OFF (e.g., the inherent or parasitic capacitance associated with the input terminal within the multiplexer 132).

A DUT 110 outputting L bits of loopback I/Os 120 and M bits of DC only I/Os 122 is coupled to the PoP-HAT apparatus (e.g. the PoP-HAT board is mounted atop the DUT). The DUT 110 may be a processor PoP chip including a DDR memory interface assembled with a processor. The L bits of loopback I/Os are subjected to both AC and DC tests, and the M bits of DC only I/Os 122 are subjected to DC tests only. Each of the L bits of the loopback I/Os 120 for AC/DC testing is tied (e.g., directly connected) to a parallel connection of both a resistor 140 and inductor 142. The resistor 140 is connected to an input terminal 130_{—}i of the switch 130, and the inductor 142 is connected to an input terminal 132_{—}i_L of the multiplexer 132. A corresponding second terminal 130_{—}o of the switch 130 may be connected to a memory common mode voltage reference (e.g., VDD/2), which is usually the memory bias power divided by 2. The M bits of the DC only I/Os are connected directly to the input terminals 132_{—}i_M of the multiplexer 132. The DC characteristics measured by the test resource 192 may include continuity, leakage, V_{OH}MIN/V_{OL}MAX measurements. In one implementation, the pin continuity test is performed first before all other DC and AC testing/characterization to ensure that the test setup has been configured properly.

A control circuit 190 toggles the switch 130 to float the inputs of the multiplexer 132 or to select the inputs for coupling to the outputs of the multiplexer 132. For DC characterization, the switch 130 is toggled to the OPEN position (e.g., the loopback I/O 120 is disconnected from the reference voltage supply VDD/2) for the DC characterization. When configuring the switch 130 in the OPEN position, the loopback I/Os 120 may undergo the DC testing via the inductor 142 and the multiplexer 132, and the DC only I/Os 122 may undergo the DC testing by connecting directly to the multiplexer 132. Each of the second terminals of the multiplexer 132 may be connected to a test resource 192 (e.g., DIGCH) to facilitate DC characterization of the I/Os.

For AC loopback, the switch 130 is toggled to the CLOSED position, and the VDD/2 common mode reference voltage is coupled to each of the loopback I/Os 120 via its series load termination resistor (resistor 140). The inductor 142 electrically isolates the (parasitic) input capacitor C_{S-OFF} of the multiplexer 132 from the AC loopback path. The resistor 140, in combination with switch 130 R_{DS}-ON resistance, provides loopback I/O transmission line termination, and under this bias condition, symmetrical I_{OH}/I_{OL} transmission line loading during the AC testing. In one implementation, the multiplexer 132 and the switch 130 operate in a complimentary fashion. When the switch 130 is CLOSED (e.g., the input terminal 130_{—}i is connected to the output terminal 130_{—}o), the multiplexer 132 is set to an off-state and, vice versa. For example, the closing of L-bit switches within the switch 130 may simultaneously float all the multiplexer 132 through-connections to afford uniform inductor output capacitance loading on the inductor 142. In one example, the multiplexer 132 decouples at least one loopback I/O 120 to the test resource 192 in response to the switch 130 been selected to couple the at least one terminal of the integrated circuit device to the termination circuit for the AC loopback.

In one implementation, the inductive reactance (X_{L}) of the inductor 142 is configured to counteract (e.g., to cancel) the reactance (X_{C}) of the input terminal (132_{—}i_L) of the multiplexer 132 for the AC loopback and testing (e.g., the multiplexer 132 is in an OFF state). Such scheme allows for high fidelity in the AC measurements. In one implementation, the series combination of inductance of the inductor 142 and the capacitance of the (parasitic) capacitor C_{S-OFF} establish a signal path impedance that is substantial higher than the 50 ohm impedance of the AC path (e.g., aggregate of the resistor 140 at, e.g., 43 ohm and the ON resistance R_{DS}-ON of switch 130 at, e.g., 7 ohm) over the frequency range of interest. In one case, without the inductor 142, the OFF-state capacitive reactance (X_{C}) of the multiplexer 132 may adversely compromise the AC testing.

In another implementation, the DC characterization and the AC loopback may be performed concurrently to characterize a DC offset (e.g. common mode voltage) in the AC operations of the I/O terminals. The switch 130 is in the CLOSED-state and connects the loopback I/O 120 to the reference voltage supply VDD/2. Concurrently, the multiplexer 132 connects the loopback I/Os 120 to the outputs 123 and the test resource 192. In this configuration, the test resource 192 is able to obtain an average DC value of the loopback I/O 120 during the AC loopback process.

In one implementation, the electrical current-resistance (I-R) loss through the circuit elements of FIG. 1 is calibrated prior to the AC and DC testing. In one example, the DC offset may be utilized for such purpose.

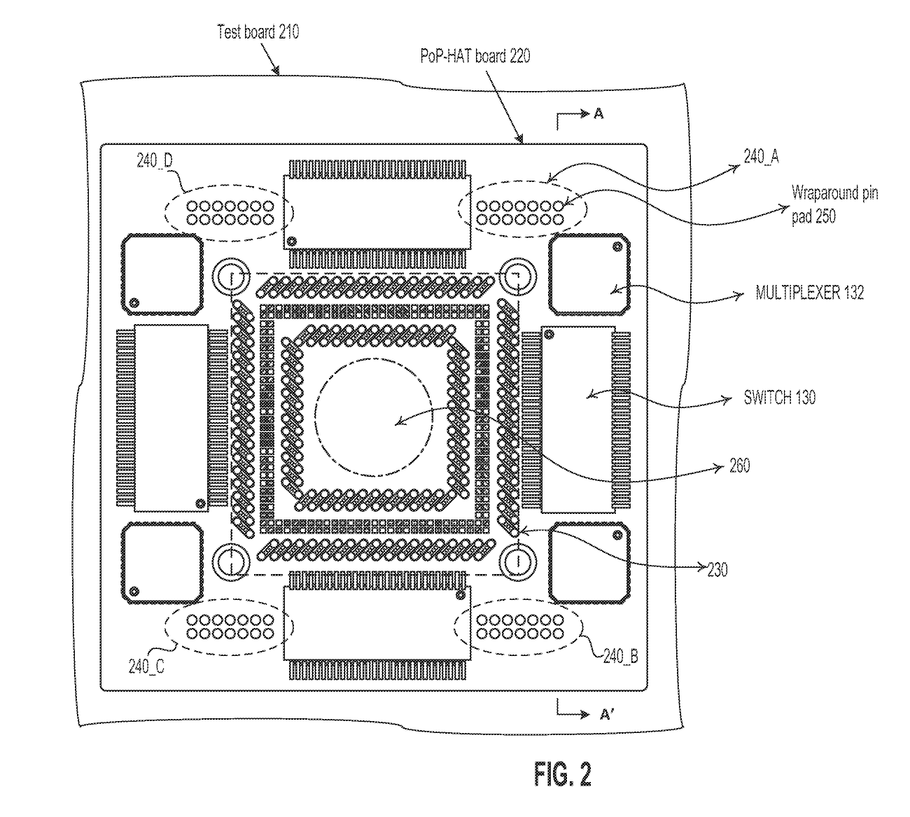

FIG. 2 is a diagram of a top view of an exemplary PoP-HAT apparatus. In one example, the PoP-HAT apparatus includes the PoP-HAT board 220 (e.g., CCA) coupled to a DUT 110 (not shown) on its bottom side and mounted on a test board 210. The test board 210 is an example of a resource to characterize the signals of the DUT 110. The PoP-HAT board 220 incorporates multiple switches 130 (e.g., each switch 130 may be a 24-bit SPST) and multiplexers 132 (e.g., each multiplexer 132 may be a 16:1 multiplexer IC). The PoP-HAT board 220 may further incorporate the resistors 140 and inductors 142 (230) as described with FIG. 1. The power (e.g., VDD and ground), control, and other digital channels for the switches 130 and the multiplexers 132 and other connections to the PoP-HAT board 220 are provided by groups of wraparound pin connection points (pads) 250. The concept of wraparound is known is the art, and in one example, the wraparound pin connection points (pads) 250 warp around the DUT 110. FIG. 2 depicts four groups of the wraparound pins (240_A, 240_B, 240_C, and 240_D) located in each corner of the PoP-HAT board 220. These wraparound pin pads 250 facilitate connectivity with the test board 210 via spring-loaded wraparound pins 350 (not shown).

In one aspect, the PoP-HAT board 220 fits within a 34 mm by 34 mm envelope. This form factor may reside within the standard load board size with a 40 mm DUT horizontal center to center spacing. One advantage of the embodiment shown is that all components perform over the −40° to +125° C. operating temperature range. In one implementation, the single pass testing, e.g., including the described DC characterization and the AC loopback, is performed in a continuous heated environment (e.g., performed at a predetermine temperature or temperature range). This form factor allows the PoP-HAT board 220 to be used with a TFU hand test device and also in a chambered or heated chuck high-temperature device high volume production test set up. However, additional sizes are contemplated and intended to be covered by the disclosure contained herein. A heatsink pass-through hole or handler vacuum cup pick up point 260 is located at the center of the PoP-HAT board 220.

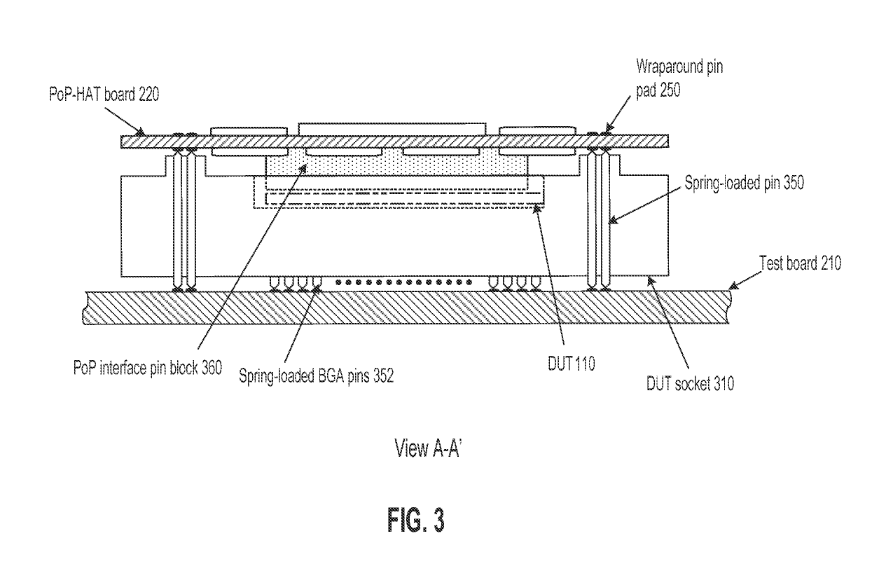

FIG. 3 is a block diagram of a side view of an exemplary PoP-HAT apparatus engaged with a test board. FIG. 3 depicts the side view along the A-A′ axis of FIG. 2. The PoP-HAT board 220 is engaged with the DUT 110 and test board 210 via a DUT socket 310. A DUT 110 is incorporated within the DUT socket 310. The DUT socket 310 communicates with the PoP-HAT board 220 via spring-loaded pins 350. The DUT communicates with the PoP-HAT board 220 by way of PoP interface pin block 360 and with the test board 210 via spring-loaded BGA pins 352. The configuration includes PoP-HAT wraparound pin pads 250 which communicate with spring-loaded pins 350. In another embodiment, the PoP-HAT board 220 may be mounted directly to the chuck of a production device handler (not shown).

In one embodiment, the PoP-HAT system is configured to detect a misalignment between the PoP-HAT board 220 and the DUT socket 310 due, for example, as a result of a faulty DUT-into-socket insertion. The PoP-HAT control circuits (e.g., control circuit 190) generates a tester DUT PoP-HAT attachment lock enable (HAT-LOK_EN) command and conveys a HAT-LOK request to the PoP-HAT board 220. If the PoP-HAT board 220 is firmly engaged with the DUT socket 310, a PoP-HAT lock acknowledgement (HAT-LOK_RTN) is returned. Upon receiving the HAT-LOK_RTN signal, the PoP-HAT control circuit enables all the PoP-HAT DC bias supplies and establishes switch 130 and the multiplexer 132 functional control. The tester, upon test completion, deasserts the HAT-LOK_EN and forcibly discharges (depletes charge on) all the PoP-HAT bias voltages to ensure that the PoP-HAT board 220 is electrically neutral (has zero residual electrical charge) upon the PoP-HAT board 220 disengagement from the DUT socket 310. This engagement/disengagement bias elimination ensures that the DUT 110 PoP interface is never exposed to any bias potential other than zero volts DC while not under active tester evaluation.

In one implementation, the PoP-HAT control circuit (e.g., control circuit 190) ensures the PoP-HAT board 220 is depleted of charge (e.g., charge neutral) upon the PoP-HAT board 220/DUT 110 engagement disengagement and misalignment detection. The PoP-HAT control circuit may deplete charges of the PoP-HAT board 220 prior to the PoP-HAT board 220 to DUT 110 engagement. The PoP-HAT control circuit may deplete charges of the PoP-HAT board 220 prior to the PoP-HAT board 220 to DUT 110 disengagement. Further, as described above, the PoP-HAT control circuit may deplete charges of the PoP-HAT board 220 upon a misalignment detection. Such measures ensure that the DUT 110 be not damaged accidentally.

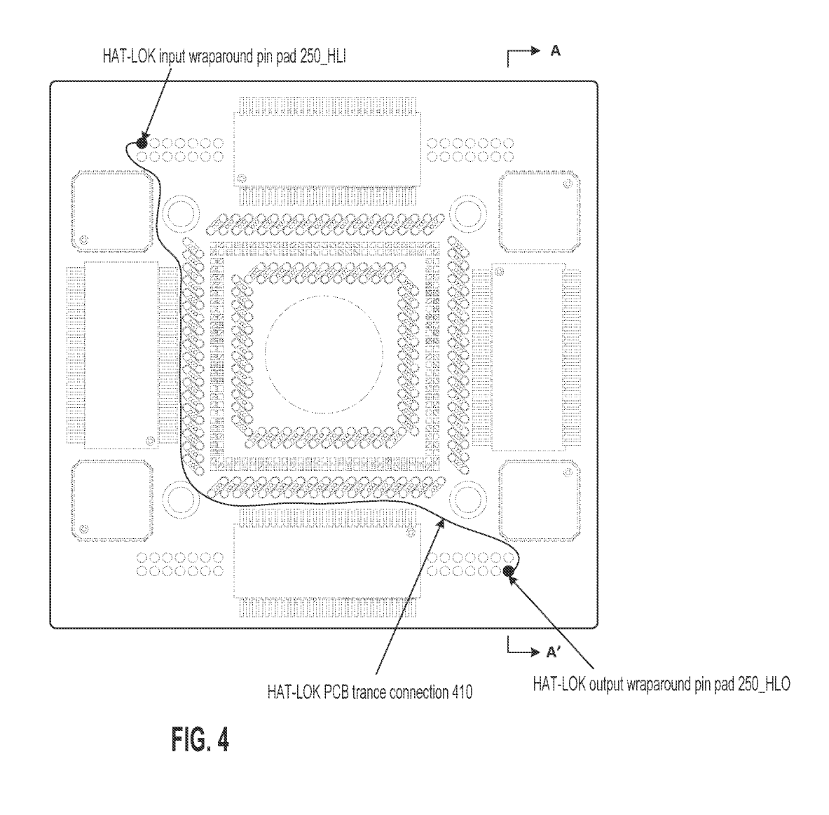

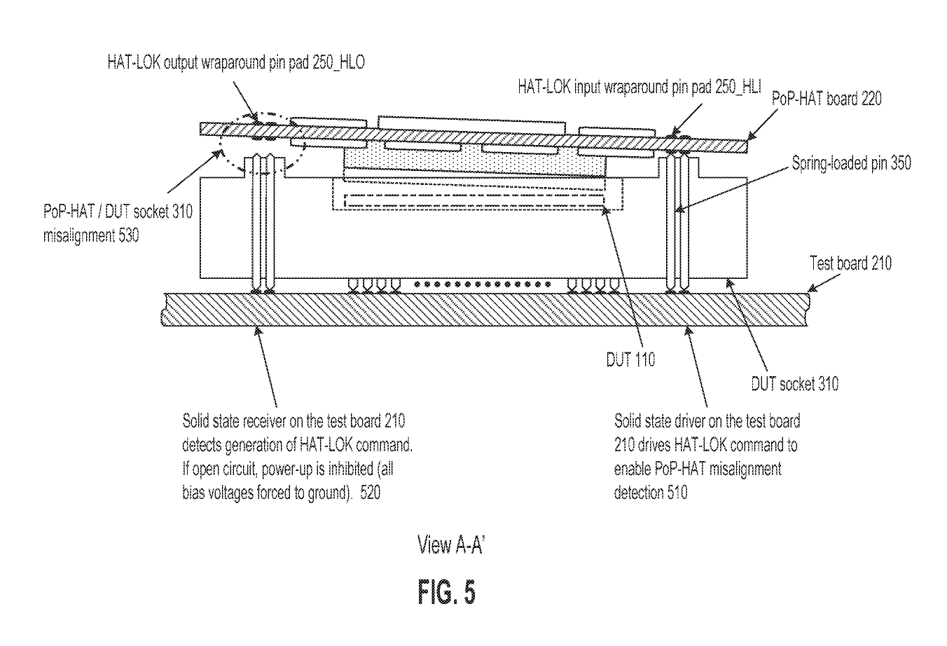

FIGS. 4 and 5 illustrate the above features. FIG. 4 is a block diagram illustrating a connection for a request command of an exemplary misalignment detection configuration. The HAT-LOK input wraparound pin pad 250_HLI is electrically connected to the HAT-LOK output wraparound pin pad 250_HLO via the HAT-LOK PCB trance connection 410. FIG. 5 is a block diagram illustrating a PoP-HAT board misalignment. In one implementation, a solid state driver (not shown) on the test board 210 drives the HAT-LOK command to enable PoP-HAT misalignment detection (510). The HAT-LOK command is provided to the HAT-LOK input wraparound pin pad 250_HLI via the spring-loaded pin 350. The HAT-LOK output wraparound pin pad 250_HLO receives the HAT-LOK command from the HAT-LOK input wraparound pin pad 250_HLI via the HAT-LOK PCB trance connection 410. In parallel, a solid state receiver (not shown) on the test board 210 may detect via, e.g., a trace on the test board 210, the signal of the HAT-LOK command. In a case the solid state receiver does not receive the HAT-LOK command signal from the HAT-LOK output wraparound pin pad 250_HLO due to a misalignment (530), the PoP control circuit may inhibit the power-up (e.g., inhibit providing power or charge depletion) of the PoP-HAT system (520). In one example, the wraparound connection provides an example of means for detecting physical misalignment. In one implementation, a DC operation bias is provided by way of wraparound pin connection means (e.g., the HAT-LOK input wraparound pin pad 250_HLI, the HAT-LOK PCB trance connection 410, and the wraparound pin pad 250_HLO). The one implementation, a connectivity test and/or operation inputs is provided via the wraparound pin connection means.

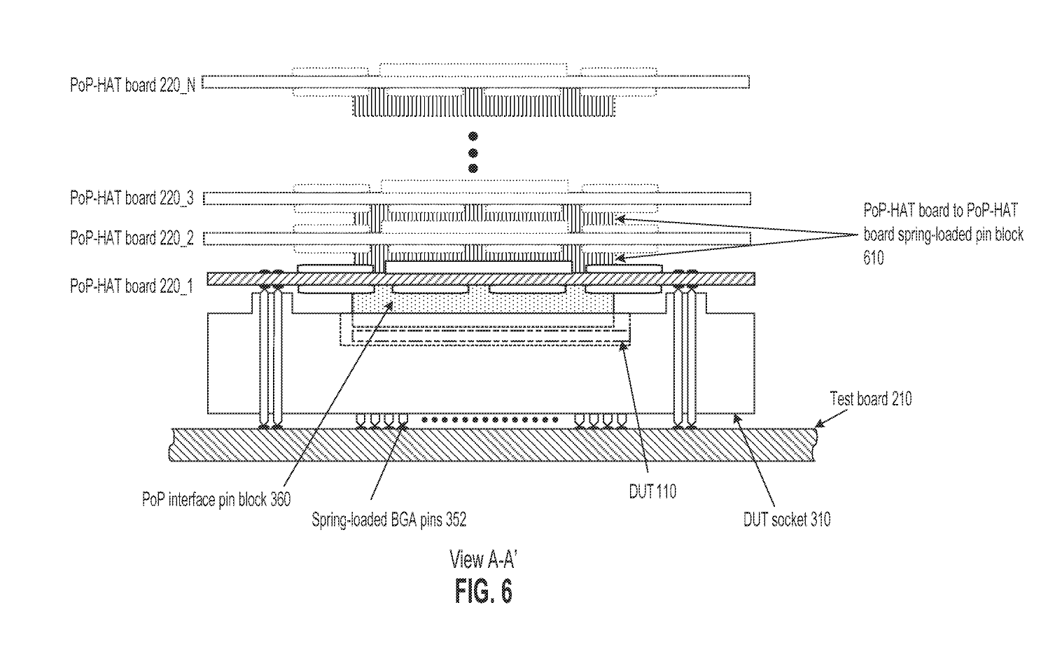

FIG. 6 is a block diagram of an exemplary PoP-HAT configuration with multiple PoP-HAT boards that serve to accommodate the test of wider individual DDR memory data bus widths and/or an increase in total number of whole memory interface to be evaluated. A total of N PoP-HAT boards (220_1, 220_2, . . . , 220_N) are depicted. In one implementation, the PoP-HAT board 220_1 is engaged with the test board 210. The PoP-HAT board 220_2 is engaged with the PoP-HAT board 220_1 (e.g., disposed on top thereof) via the spring-loaded pin block 610, and so forth. In one implementation, the test board 210 may operate to characterize the DUT 110 coupled thereto via the PoP-HAT expansion boards 220-1 and 220-2. In one example, the stacking of the PoP-HAT expansion boards 220-1 and 220-2 is configured to characterize of wider memory bus widths and/or increased number of I/O pins for the DUT 110. For example, a first set of pins of the DUT 110 may be connected to the test board 210 via the PoP-HAT expansion boards 220-1, and the second set of pins the DUT 110 may be connected to the test board 210 via the PoP-HAT expansion boards 220-2, and so forth.

The embodiments described herein provide for a PoP single pass test regimen. This single pass testing regimen provides characteristic impedance termination to DDR I/Os (e.g., loopback I/O 120) and also provides for complete DDR I/O DC measurement capability. In one aspect, the embodiments described reduce the number of digital channels required for testing from L+M memory bits/DUT to as few as two if pin-to-pin leakage measurement is required or one if not. Moreover, because testing may be performed in a single pass, all second testing pass part handling is eliminated as is second pass retesting for continuity failure. Less handling also results in reduced damage to the DUT pin contacts (e.g., pins of the DDR memory and/or BGA interface). An additional benefit is reduced exposure to possible ESD damage because less handling is required for complete testing. Furthermore, this fundamental technology may be utilized to facilitate any number of high-speed serial or parallel I/O types (including DDR or other memory I/O types accessible only via the device BGA bottom pins) to support at-device-pin based AC loopback and DC characteristics measurements. Transmission line termination impedance and requisite inductor value may be application specific and selected in conjunction with the individual SPST switch and the multiplexer IC characteristics. This embodiment may be easily configured to incorporate additional test capability as DUT complexity may increase over time. Although exemplary DDR AC/DC I/O testing is described herein, the technology of this apparatus is suitable to a wide variety of high-speed I/O type AC/DC characterization test.

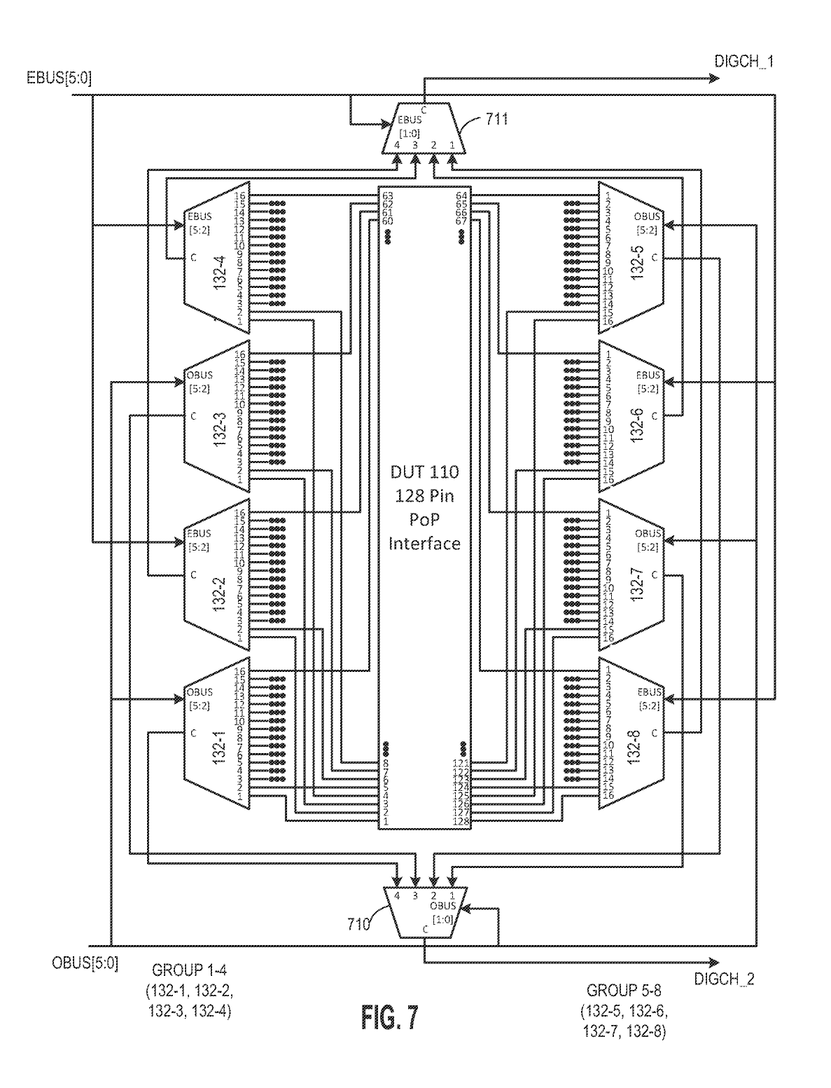

FIG. 7 is a block diagram of an exemplary PoP-HAT configuration for pin-to-pin and pin-to-package leakage current characterization. In one implementation, the L+M bit multiplexer 132 may include a number of discrete addressable 16:1 multiplexer ICs (132-1, 132-2 . . . 132-8) with inputs interleaved and addressed in such a way as to support DUT 110 memory pin/pin (i.e. adjacent pin) and pin/package leakage current characterization. By way of example (see FIG. 7), eight 16:1 multiplexers (132-1, 132-2 . . . 132-8) may be divided into even and odd numbered devices with all even numbered components address by a common input selection bus (e.g., EBUS). The odd numbered multiplexers are likewise addressed by a second common address bus (e.g., OBUS). The four multiplexer outputs from each group are further aggregated by individual 4:1 multiplexers (aggregation multiplexer 710, 711) addressed by the least significant bits (LSBs) of respective even/odd address buses. In this example, the eight multiplexers are divided into two groups of four each, group 1-4 and group 5-8, with each assigned two odd (e.g. devices 1 and 3) and two odd numbered devices (e.g. devices 2 and 4). The even and odd numbered multiplexer groups are collectively afforded a common tester resource, (e.g. DIGCH 1 and DIGCH 2, respectively). In group 1-4 with each multiplexer having inputs 1-16, even and odd multiplexer inputs are interleaved and successively connected to physically adjacent DUT 110 PoP package memory pins as follows: 1.1 (i.e. multiplexer 1, input 1), 2.1 (i.e. multiplexer 2, input 1), 3.1 (i.e. multiplexer 3, input 1), 4.1 (i.e. multiplexer 4, input 1), 1.2 (i.e. multiplexer 1, input 2), 2.2 (i.e. multiplexer 2, input 2), 3.2 (i.e. multiplexer 3, input 2), 4.2 (i.e. multiplexer 4, input 2), and so on. Group 5-8 are likewise interleaved with multiplexer input 5.1 immediately following memory PoP pin multiplexer connection 4.16 (e.g. 3.16, 4.16, 5.1, 6.1, etc). In this example embodiment, a DUT 110 with 128 PoP memory pins (8×16) may have each pin adjacency accessible via two tester resources from which pin/pin leakage current may be measured. Further, with selective aggregation multiplexer addressing, pairs on non-adjacent DUT 110 pins may have their respective pin/package leakage current determined as well.

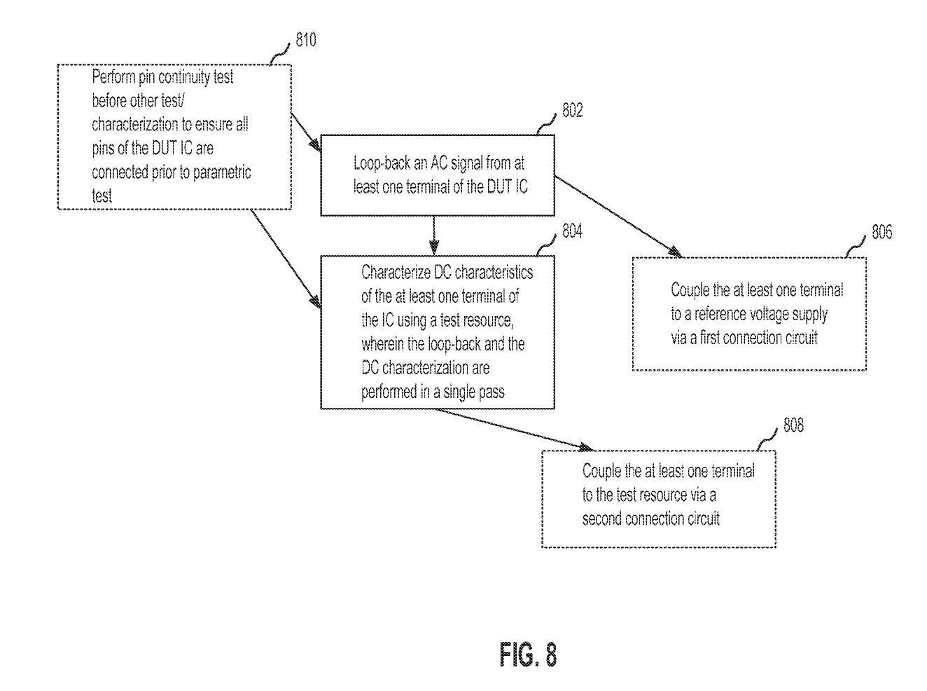

FIG. 8 is a flowchart of operations of an exemplary PoP-HAT apparatus. The steps drawn in dotted lines may be optional. At 804, DC characteristics of the at least one terminal of the IC are characterized using a test resource. At 802, an AC signal is looped back from at least one terminal of the IC. For example, an AC signal may be outputted by the loopback I/O 120 of the DUT 110. The AC signal provided to the reference voltage supply VDD/2 via the resistor 140 and the switch 130, and looped back to the loopback I/O 120. In one example, the resistor 140 may provide the means for looping back an AC signal to one terminal of an IC. The loop-back and the DC characterization are performed in a single pass (i.e. one-pass). For example, the DC characterization may be performed by a test resource attached to outputs 123 of the multiplexer 132, via the inductor 142. The AC loopback (via the switch 130) and the DC characterization (via the multiplexer 132) may be performed in a single pass via the settings of the switch 130 and the multiplexer 132. In one example, the inductor 142 provides the means to characterize the DC characteristics of the at least one terminal of the IC.

At 806, the at least one terminal is coupled to a reference voltage supply via a first connection circuit. For example, the loopback I/O 120 is connected to the reference voltage supply VDD/2 via the switch 130. In one example, the control circuit 190 provides the means for coupling the at least one terminal to a reference voltage supply via a first connection circuit (e.g., the switch 130). At 808, the at least one terminal is coupled to the test resource via a first connection circuit. For example, the loopback I/O 120 is connected to the test resource coupled to the outputs 123 via the multiplexer 132. In one example, the control circuit 190 provides the means for coupling the at least one terminal to a test resource via a second connection circuit (e.g., the multiplexer 132).

In another aspect, at 810, a pin continuity test is performed before other test/characterization to ensure all pins of the DUT IC are connected prior to parametric test. Additional examples are described above with FIGS. 1-6.

For a firmware and/or software implementation, the methodologies may be implemented with modules (e.g., procedures, functions, and the like) that perform the functions described herein. Any machine-readable medium tangibly embodying instructions may be used in implementing. The control circuit may be implemented with hardware, software, or combinations thereof. The hardware may include logic gates to perform the functions described herein, processor(s) performing those functions, logic gates generating the signals described herein, or combinations thereof.

It is understood that the specific order or hierarchy of steps in the processes disclosed is an illustration of exemplary approaches. Based upon design preferences, it is understood that the specific order or hierarchy of steps in the processes may be rearranged. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

It is to be understood that the claims are not limited to the precise configuration and components illustrated above. Various modifications, changes and variations may be made in the arrangement, operation and details of the systems, methods, and apparatus described herein without departing from the scope of the claims.

What is claimed is:

1. An apparatus for characterizing an integrated circuit device, comprising:
a first connection circuit configured to selectively couple at least one terminal of the integrated circuit device to a termination circuit for alternating current (AC) loopback; and
a second connection circuit configured to selectively couple the at least one terminal of the integrated circuit device to a test resource for direct current (DC) characterization.

2. The apparatus of claim 1, further comprising an inductive element, via which the at least one terminal of the integrated circuit device is coupled to the second connection circuit.

3. The apparatus of claim 2, wherein a reactance of the inductive element is configured to counteract a reactance of a parasitic capacitor of the second connection circuit.

4. The apparatus of claim 1, wherein the termination circuit comprises a reference voltage supply.

5. The apparatus of claim 4, further comprises a resistive element, via which the at least one terminal of the integrated circuit device is coupled to the first connection circuit.

6. The apparatus of claim 5, wherein a resistance of the resistive element and a resistance of the first connection circuit in a connected state provide a transmission line termination for the AC loopback.

7. The apparatus of claim 1, where the second connection circuit is configured to decouple the at least one terminal to the test resource in response to the first connection circuit been selected to couple the at least one terminal of the integrated circuit device to the termination circuit for the AC loopback.

8. The apparatus of claim 1, wherein the first connection circuit comprises a switch, and the second connection circuit comprises a multiplexer.

9. The apparatus of claim 1, wherein the second connection circuit is further configured to selectively couple a second terminal to the test resource, and wherein the second terminal is not coupled to the first connection circuit.

10. The apparatus of claim 1, wherein the AC loopback and the DC characterization of the at least one terminal is performed in a one-pass test.

11. The apparatus of claim 10, wherein the AC loopback and the DC characterization of the at least one terminal are performed concurrently.

12. The apparatus of claim 10, wherein the AC loopback and the DC characterization of the at least one terminal are performed in a predetermined temperature range.

13. The apparatus of claim 10, wherein a pin continuity test is performed first before all other testing or characterization.

14. An apparatus for characterizing an integrated circuit, comprising:
a board configured to couple to the integrated circuit and to a test resource for characterizing the integrated circuit, wherein the board comprises means for detecting physical misalignment of the board and the test resource.

15. The apparatus of claim 14, wherein a power up of the board is inhibited in response to a detection of physical misalignment.

16. The apparatus of claim 14, wherein the board is coupled to the test resource via a spring-loaded pin.

17. The apparatus of claim 14, wherein the means for detecting physical misalignment comprises a wraparound pin connection.

18. The apparatus of claim 17, wherein the wraparound pin connection comprises pins on the board connected by a trace connection wrapping around the integrated circuit.

19. The apparatus of claim 17, wherein a DC operation bias is provided via the wraparound pin connection.

20. The apparatus of claim 17, wherein a connectivity test is provided via the wraparound pin connection.

21. The apparatus of claim 14, further comprising a second board configured to stack with the board, wherein a first set of pins of the integrated circuit is coupled to the test resource via the board and the second set of pins of the integrated circuit is coupled to test resource via the second board.

22. An apparatus for characterizing an integrated circuit, comprising:
a board configured to couple to the integrated circuit and to a test resource for characterizing the integrated circuit; and
a control circuit configured to deplete charges from the board prior to the board engaging or disengaging the integrated circuit.
